(19) United States
(12) Patent Application Publication
(10) Pub. No.: US 2005/0152109 A1
(43) Pub. Date: Jul. 14, 2005

(54) Monitor

(75) Inventors: Hyun-yong Choi, Chuncheon-si (KR); Jun-soo Jeong, Suwon-si (KR); Woo-nam Byun, Suwon-si (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 11/034,867

(22) Filed: Jan. 14, 2005

(30) Foreign Application Priority Data
Jan. 14, 2004 (JP) 2004-2724
Jan. 19, 2004 (JP) 2004-3935

(51) Int. Cl. H05K 7/00

(52) U.S. Cl. 361/683

(57) ABSTRACT

A monitor having a rotable connection terminal. A monitor body to display an image is coupled to a supporting base with an adjustable link which permits the monitor body to be positioned at various angles relative to the base. The connection terminal is operatively to the monitor body and adapted to receive a second cable which provides an operational signal for the monitor body. The connection terminal is rotatably coupled to one of the base and the monitor body to permit the second cable to be connected to the connection terminal from various angles relative to the base, whereby the position of the second cable may be conveniently located for operation of the monitor according to a mounting orientation of the monitor base, contributing to an aesthetically pleasing appearance of the monitor.

### CROSS-REFERENCE TO RELATED APPLICATIONS

This application claims the benefit of Korean Patent Application No. 2004-2724, filed Jan. 14, 2004 and Korean Patent Application No. 2004-3935, filed Jan. 19, 2004 in the Korean Intellectual Property Office, the disclosures of which are incorporated herein by reference.

### BACKGROUND OF THE INVENTION

1. Field of the Invention

The present invention relates to a monitor, and more particularly, to a monitor having an improved structure between a base and a connecting terminal to which a cable is connected for transmitting an external signal.

2. Description of the Related Art

Generally, a monitor comprises a monitor body to display an image, and a base to support the monitor body. The monitor displays the image and/or makes a sound based on an external signal received from an external source, wherein the monitor is connected with a predetermined cable to receive the external signal such as a video signal, an audio signal, power, etc., through the cable.

FIGS. 1 and 2 show a conventional monitor 101. As shown in FIGS. 1 and 2, the conventional monitor 101 comprises a base 130 seated on a table 160 (FIG. 1) or mounted to a wall 170 (FIG. 2); a monitor body 110 to display an image; a link 120 linking the base 130 with the monitor body 110; a connecting terminal 141 provided in a back of the base 130 and to which a cable 103 is connected for transmitting an external signal; and hinges 111 provided between a lower portion of the link 120 and the base 130 and an upper portion of the link 120 and the monitor body 110 and supporting the monitor body 110 to be rotatable with respect to the base 130.

The connecting terminal 141 is connectable with a cable connector 105 provided in an end of the cable 103 and receives the external signal such as a video signal, an audio signal, power, etc.

In the conventional monitor 101, the monitor body 110 is rotatable with respect to the base 130 by the hinges 111, and displays an image or makes a sound based on the external signal received through the connecting terminal 141.

However, in the conventional monitor 101, when the base 130 is mounted to the wall 170 as shown in FIG. 2, the connecting terminal 141 is upwardly oriented. Therefore, not only is it inconvenient to connect the cable 103 to the connecting terminal 141, but also an outer appearance is disfigured because the cable 103 connected to the connecting terminal 141 is upwardly exposed.

### SUMMARY OF THE INVENTION

Accordingly, it is an aspect of the present invention to provide a monitor in which a cable for transmitting an external signal is conveniently and beautifully connected.

The foregoing and/or other aspects of the present invention are achieved by providing a monitor comprising a monitor body to display an image, and a base supporting the monitor body, the monitor further comprising: a link provided between the monitor body and the base and allowing the monitor body to be rotatable with respect to the base; and a terminal assembly comprising a connecting terminal to which a first cable for transmitting an external signal is connected, and a terminal supporter supporting the connecting terminal and rotatably coupled to the base.

According to an aspect of the invention, the monitor further comprises a base hinge provided between the link and the base and rotatably coupling the link with the base; and a monitor hinge provided between the link and the monitor and rotatably coupling the link with the monitor.

According to an aspect of the invention, the base is formed with a link housing to accommodate the link.

According to an aspect of the invention, the terminal assembly is placed in a front of the link housing of the base.

According to an aspect of the invention, the base is formed with a first cable housing to accommodate at least a part of the first cable.

According to an aspect of the invention, the monitor further comprises a base bracket to be coupled to the base and an inclined surface so that the base is mounted to the inclined surface.

According to an aspect of the invention, the monitor further comprises a terminal hinge provided between the terminal assembly and the base, and supporting the terminal assembly to be rotatable to allow the connecting terminal to be oriented frontward or backward with respect to the base.

According to an aspect of the invention, the terminal hinge comprises a terminal hinge shaft provided in one of the terminal supporter and the base and forming a rotating axis parallel with a rotating axis of the monitor body, and a terminal hinge shaft accommodating part provided in the other one of the terminal supporter and the base and rotatably accommodating the terminal hinge shaft.

According to an aspect of the invention, the terminal hinge shaft is formed with a second cable through hole through which a second cable connected to the connecting terminal inside the terminal supporter is passed.

According to another aspect of the present invention, the above and other aspects may be also achieved by providing a monitor comprising a monitor body to display an image, and a base supporting the monitor body, the monitor further comprising: a link provided between the monitor body and the base; a monitor hinge provided between the link and the monitor body and rotatably coupling the link with the monitor body; and a terminal assembly comprising a connecting terminal to which a first cable for transmitting an external signal is connected, and a terminal supporter supporting the connecting terminal and rotatably coupled to one of the link and the monitor hinge.

According to an aspect of the invention, the monitor hinge comprises a monitor supporter coupled to the monitor body, and a monitor hinge shaft coupled between the monitor supporter and the link and allowing the monitor supporter to be rotatable with respect to the link.

According to an aspect of the invention, in an end portion of the link coupled to the monitor hinge shaft is formed a terminal assembly housing to accommodate the terminal assembly.

According to an aspect of the invention, the terminal assembly is coupled to the monitor hinge shaft and is rotatable about a rotating axis of the monitor hinge shaft.

According to an aspect of the invention, the monitor hinge shaft is formed with a second cable through hole through which a second cable connected to the connecting terminal is passed.

According to an aspect of the invention, the monitor further comprises a base hinge provided between the link and the base and rotatably coupling the link with the base.

According to an aspect of the invention, the monitor further comprises a base bracket to be coupled to the base and an inclined surface so that the base is mounted to the inclined surface.

Additional aspects and/or advantages of the invention will be set forth in part in the description which follows and, in part, will be obvious from the description, or may be learned by practice of the invention.

### BRIEF DESCRIPTION OF THE DRAWINGS

The above and/or other aspects and advantages of the present invention will become apparent and more readily appreciated from the following description of the embodiments, taken in conjunction with the accompany drawings of which:

FIG. 1 is a rear perspective view of a conventional monitor;

FIG. 2 is a side view of the conventional monitor mounted to a wall;

FIG. 3 is a rear perspective view of a monitor according to a first embodiment of the present invention;

FIG. 4 is a rear perspective view of the monitor of FIG. 3 adapted to be mounted to an inclined surface;

FIG. 5A is a partially exploded perspective view of a base of the monitor of FIG. 3;

FIG. 5B is an enlarged view of a portion of the base shown in FIG. 3;

FIG. 6 is a side view of the monitor of FIG. 3 shown seated on a horizontal surface;

FIG. 7 is a side view of the monitor of FIG. 3 shown mounted to an inclined surface;

FIG. 8 is a rear perspective view of a monitor according to a second embodiment of the present invention;

FIG. 9 is a rear perspective view of the monitor of FIG. 8 adapted to be mounted to an inclined surface;

FIG. 10 is a partially exploded perspective view of the monitor of FIG. 8;

FIG. 11 is a side view of the monitor of FIG. 8 shown seated on the horizontal surface; and

FIG. 12 is a side view of the monitor of FIG. 8 shown mounted to the inclined surface.

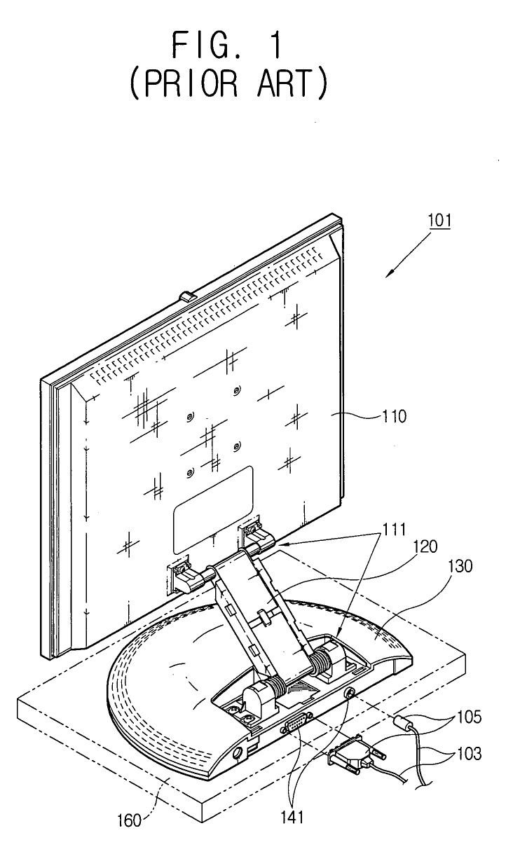

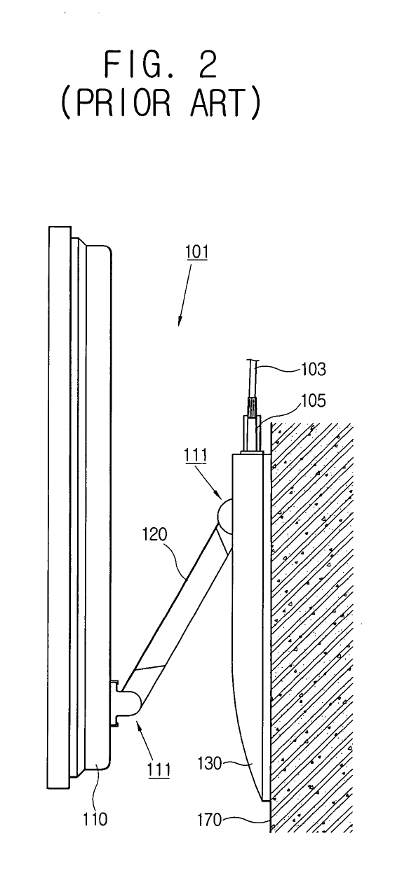

### DETAILED DESCRIPTION OF THE PREFERRED EMBODIMENTS

Reference will now be made in detail to the embodiments of the present invention, examples of which are illustrated in the accompanying drawings, wherein like reference numerals refer to like elements throughout. The embodiments are described below in order to explain the present invention by referring to the figures.

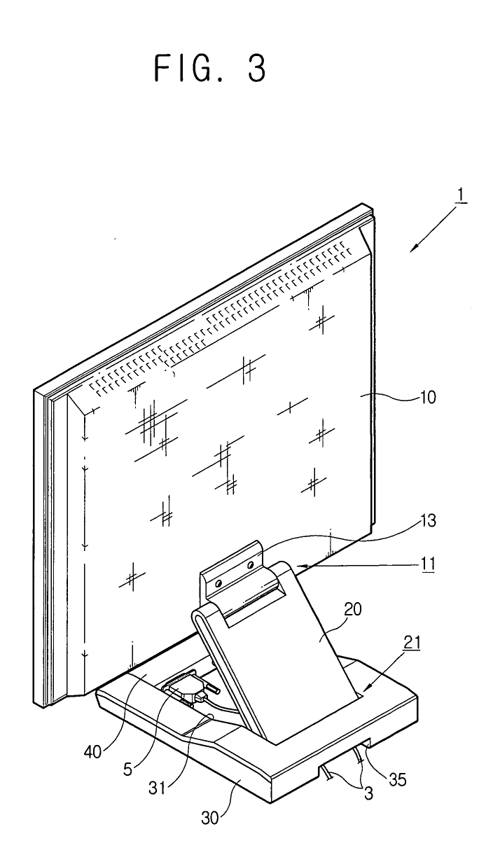

In a first embodiment of the invention, as shown in FIGS. 3 through 7, a monitor 1 comprises a monitor body 10 to display an image; a base 30 supporting the monitor body 10; a link 20 provided between the monitor body 10 and the base 30 and allowing the monitor body 10 to be rotatable with respect to the base 30; and a terminal assembly 40 rotatably coupled to the base 30 and to which a first cable 3 for transmitting an external signal is connectable.

Further, the monitor 1 comprises a base hinge 21 provided between the link 20 and the base 30 and rotatably coupling the link 20 with the base 30; and a monitor hinge 11 provided between the link 20 and the monitor body 10 and rotatably coupling the link 20 with the monitor body 10. To mount the base 30 to an inclined surface 70, the monitor 1 further comprises a base bracket 80 for coupling the base 30 and the inclined surface 70.

The monitor hinge 11 comprises a monitor supporter 13 integrally coupled to the monitor body 10, and a monitor hinge shaft 15 coupling the monitor supporter 13 and the link 20 and allowing the monitor body 10 to be rotatable with respect to the link 20.

The base hinge 21 comprises a base supporter (not numbered) integrally coupled to the base 30, and a base hinge shaft 25 coupling the base supporter and the link 20 and allowing the link 20 to be rotatable with respect to the base 30.

The base 30 is seatable on a horizontal surface 60 such as a table or mountable to the inclined surface 70 such as a wall. According to an aspect of the invention, the base 30 is formed with a link housing 31 to accommodate the link 20. Further, the base 30 is formed with a projection holder 33 placed corresponding to a projection 81 (to be described later) of the base bracket 80 to hold the projection 81 of the base bracket 80. Further, the base 30 is formed with a first cable housing 35 to partially accommodate the first cable 3.

The link housing 31 accommodates the link 20 rotatable with respect to the base 30. Hence, when the monitor 1 according to the present invention is packaged, the link 20 may be accommodated in the link housing 31 of the base 30, thereby decreasing a volume of the monitor 1 and decreasing a physical distribution cost.

The first cable housing 35 is formed by recessing a bottom of the base 30 to prevent the bottom of the base 30 from interfering with the first cable 3 when the base 30 is seated on the horizontal surface 60.

The base bracket 80 is plate shaped and comprises a plurality of the projections 81 protruding from a surface of the base bracket 80 to be inserted in and held by the projection holders 33 of the base 30, and a plurality of first coupling holes 83 to mount the base bracket 80 onto the inclined surface 70, using suitable means, such as, for example, screws 85. The base bracket 80 may further comprise a second coupling hole (not shown) to be coupled to at least one of the base 30 and the link 20 by a screw (not shown), and it should be appreciated that at least one of the base 30 and the link 20 may be formed with a screw hole (not shown) positioned corresponding to the second coupling hole of the base bracket 80 and to which the screw is coupled.

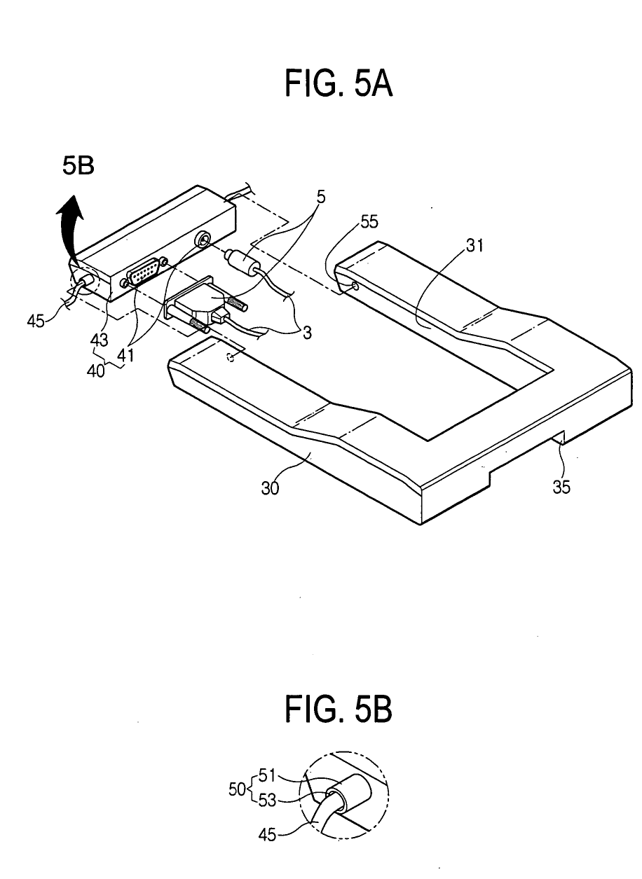

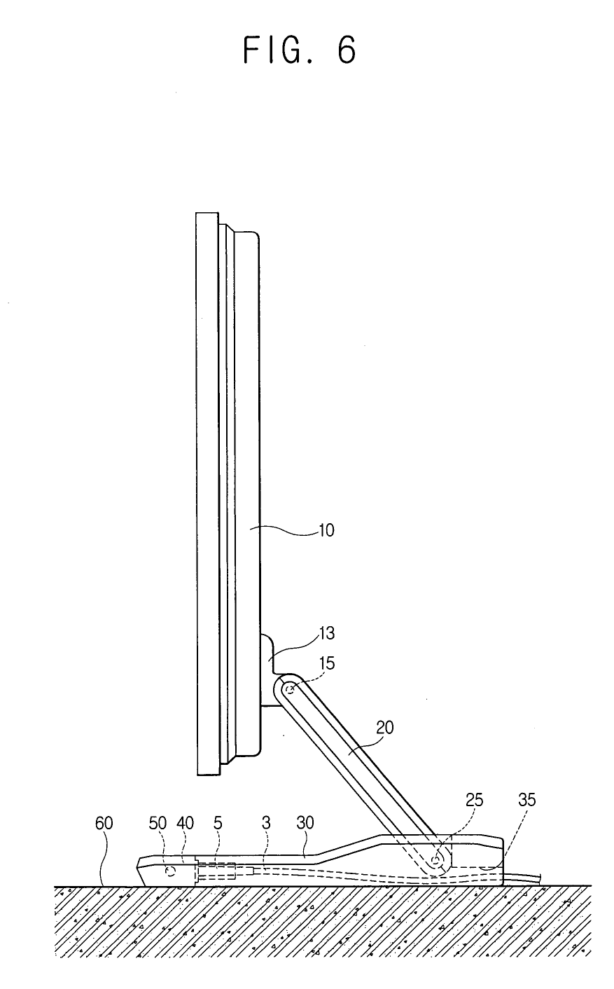

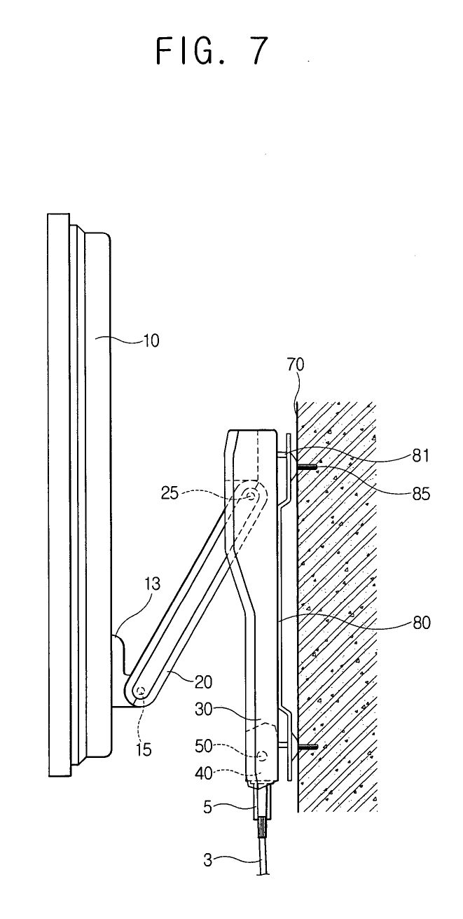

The terminal assembly 40 comprises a connecting terminal 41 to which the first cable 3 for transmitting the external signal is connected, and a terminal supporter 43 supporting the connecting terminal 41 and rotatably coupled to the base 30. A terminal hinge 50 is provided between the terminal assembly 40 and the base 30, supporting the terminal assembly 40 to be rotatable through an angle of at least 180 degrees, thereby allowing the connecting terminal 41 to be oriented at various angles including frontward and backward with respect to the base 30. For example, the terminal assembly 40 may be oriented to face toward the first cable housing 35 as shown in FIGS. 5A and 6 or oriented to face away from the first cable housing 35 as shown in FIG. 7. The terminal assembly 40 may be placed in a front of the link housing 31 of the base 30 as shown in FIG. 5A. Alternatively, the terminal assembly 40 may be placed in a rear of the link housing 31 of the base 30 and rotatably coupled to the base 30.

The connecting terminal 41 is detachably connectable with the first cable 3 to receive the external signal such as a video signal, an audio signal, power, etc. The connecting terminal 41 may be detachably connectable via a cable connector 5 provided in an end of the first cable 3, and is plurally provided to be connectable with a plurality of cable connectors 5.

The terminal supporter 43 supports the connecting terminal 41 and is rotatably coupled to a front of the link housing 31 so as to be rotatable with respect to the base 30. That is, the terminal supporter 43 is coupled to the connecting terminal 41 by a screw or the like to support the connecting terminal 41. The terminal supporter 43 accommodates a second cable 45 inwardly connected to the connecting terminal 41.

As shown in FIGS. 5A and 5B, the terminal hinge 50 comprises a terminal hinge shaft 51 provided in one of the terminal supporter 43 and the base 30 and having a rotating axis parallel with a rotating axis of the monitor body 10, and a terminal hinge shaft accommodating part 55 provided in the other one of the terminal supporter 43 and the base 30 and rotatably accommodating the terminal hinge shaft 51. In the first embodiment, the terminal hinge shaft 51 is integrally provided in opposite sides of the terminal supporter 43, and the terminal hinge shaft accommodating part 55 is provided in the base 30 to accommodate the terminal hinge shaft 51.

The terminal hinge shaft 51 may be formed with a second cable through hole 53 through which the second cable 45 may be passed and connected to the connecting terminal 41 inside the terminal supporter 43.

The second cable through hole 53 may be formed on the center of the terminal hinge shaft 51, allowing the second cable 45 to connect the connecting terminal 41 with the monitor body 10 via the base 30.

With the configuration described with respect to FIGS. 3-7, the monitor 1 according to the first embodiment of the present invention is operated as follows.

As shown in FIGS. 3 and 6, in a case of seating the monitor 1 on the horizontal surface 60, the terminal assembly 40 is rotated with respect to the base 30 to orient the connecting terminal 41 backward, that is, toward the first cable housing 35. Then, the first cable 3 is partially accommodated in the first cable housing 35 of the base 30, and the cable connector 5 provided in the end of the first cable 3 is connected to the connecting terminal 41.

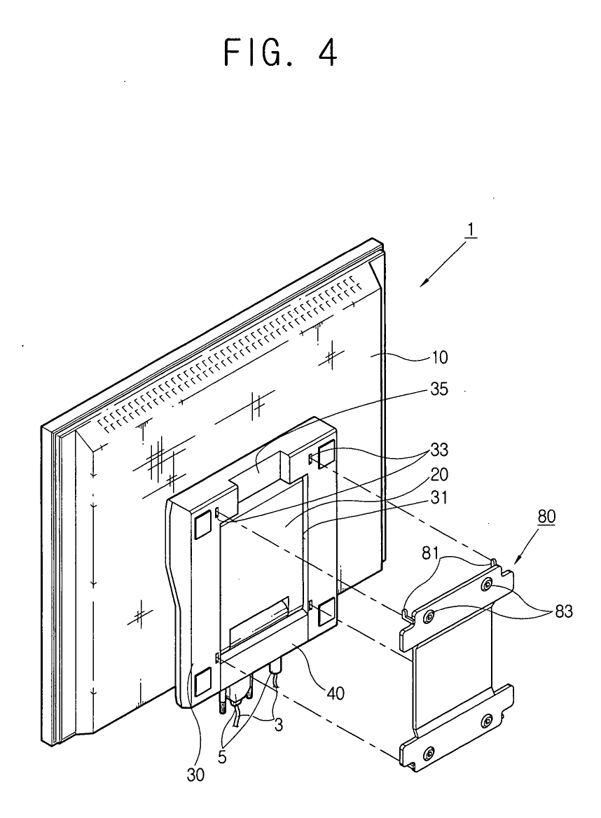

As shown in FIGS. 4 and 7, in the case of mounting the monitor 1 on the inclined surface 70, the base bracket 80 is mounted to the inclined surface 70, and the projection holders 33 of the base 30 are coupled to the projections 81 of the base bracket 80. The terminal assembly 40 is rotated with respect to the base 30 to orient the connecting terminal 41 downward, that is, away from the first cable housing 35. Then, the cable connector 5 provided in the end of the first cable 3 is connected to the connecting terminal 41 oriented downward, thereby preventing the first cable 3 from being upwardly exposed from the monitor body 10 even if the monitor 10 is tilted.

Thus, in the monitor according to the present invention, when the base is mounted to the inclined wall, the cable is not only conveniently connected because the terminal assembly connected to the cable is rotatably coupled to the base, but is also beautifully connected because the cable is prevented from being upwardly exposed from the monitor body.

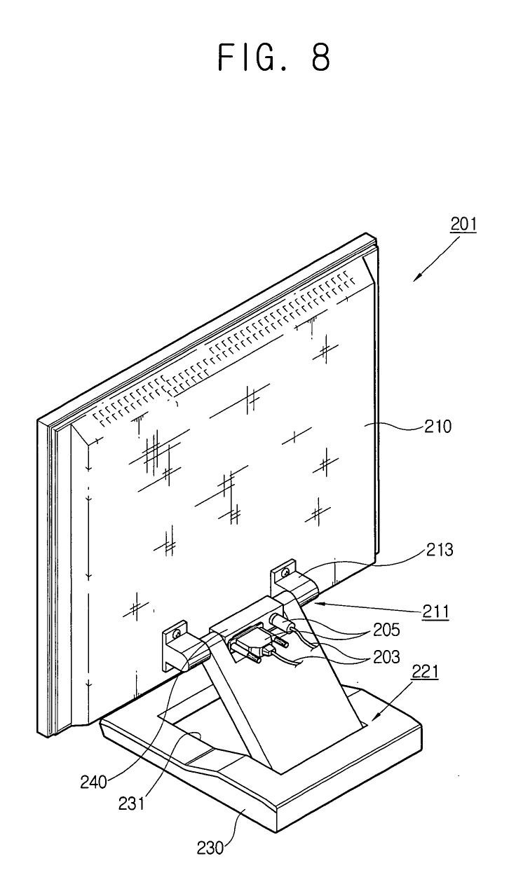

In a second embodiment of the invention, as shown in FIGS. 8 through 12, a monitor 201 comprises a monitor body 210 to display an image; a base 230 supporting the monitor body 210; a link 220 provided between the monitor body 210 and the base 230; a monitor hinge 211 provided between the link 220 and the monitor body 210 and rotatably coupling the link 220 with the monitor body 210; and a terminal assembly 240 rotatably coupled to one of the link 220 and the monitor hinge 211 and to which a first cable 203 for transmitting an external signal is connected.

Further, the monitor 201 comprises a base hinge 221 provided between the link 220 and the base 230 and rotatably coupling the link 220 with the base 230. To mount the base 230 to an inclined surface 270, the monitor 201 further comprises a base bracket 250 which may be coupled to the base 230 and the inclined surface 270.

The monitor body 210 may comprise a liquid crystal display (LCD) panel, a plasma display panel (PDP), or the like which is relatively light weight and is adaptable to manufacture as a large sized screen.

The monitor hinge 211 comprises a monitor supporter 213 integrally coupled to the monitor body 210, and a monitor hinge shaft 215 coupled between the monitor supporter 213 and the link 220, allowing the monitor body 210 to be rotatble with respect to the link 220.

A pair of monitor supporters 213 is provided and each monitor supporter 213 has a first side coupled to the monitor body 210 and a second side coupled to one of opposite sides of the link 220.

The monitor hinge shaft 215 has a first end integrally coupled to the monitor supporter 213 and a second end rotatably inserted in the link 220. That is, the first ends of the monitor hinge shafts 215 are fitted in the pair of monitor supporter 213 and rotate integrally with the monitor supporter 213. Further, the second end of each monitor hinge shaft 215 is rotatably inserted in a hinge shaft coupling part 227 provided in a first portion 220a of the link 220 and is rotated by a predetermined pressing force. Thus, the monitor body 210 is rotatable about the monitor hinge shaft 215 with respect to the link 220 by the pressing force. Here, such pressing force is easily given by a general user to tilt the monitor body 210.

The base hinge 221 comprises a base supporter (not shown) integrally coupled to the base 230, and a base hinge shaft 225 coupled between the base supporter and the link 220 and allowing the link 220 to be rotatable with respect to the base 230.

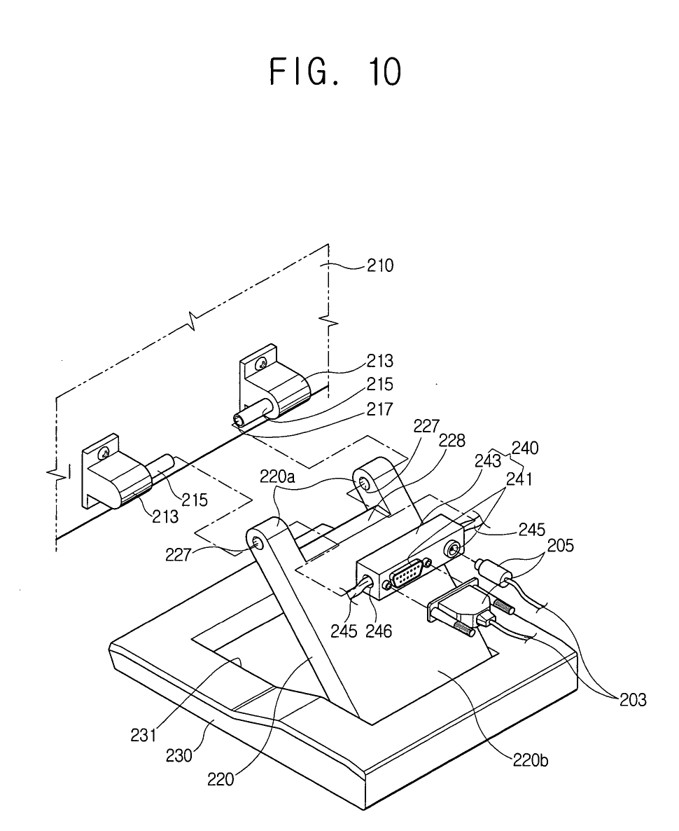

The link 220 comprises a pair of first portions 220a coupled to the monitor hinge shaft 215, and a second portion 220b coupled to the base hinge shaft 225. As shown in FIG. 10, the first portion 220a is upwardly extended from an upper opposite part of the link 220. Further, the first portion 220a is formed with the hinge shaft coupling part 227 to which the monitor hinge shaft 215 is inserted and coupled. Further, between the pair of first portions 220a is formed a terminal assembly housing 228 in which the terminal assembly 240 is rotatably accommodated.

The base 230 is seatable on a horizontal surface 260, such as a table, or mountable to the inclined surface 270, such as a wall. According to an aspect of the invention, the base 230 is formed with a link housing 231 to accommodate the link 220. Further, the base 230 is formed with a projection holder 233 placed corresponding to a projection 251 of the base bracket 250 to hold the projection 251 of the base bracket 250.

The link housing 231 accommodates the link 220 rotatable with respect to the base 230. Hence, when the monitor 201 according to the present invention is packaged, the link 220 may be accommodated in the link housing 231 of the base 230, thereby decreasing the volume of the monitor 201 and decreasing a physical distribution cost.

The base bracket 250 is shaped like a plate and comprises the plurality of projections 251 protruding from a surface of the base bracket 250 to be inserted in and held by the projection holders 233 of the base 230, and a plurality of first coupling holes 253 to mount the base bracket 250 onto the inclined surface 270 by suitable elements/techniques, such as for example, screws 255. The base bracket 250 may further comprise a second coupling hole (not shown) to be coupled to at least one of the base 230 and the link 220 by a screw (not shown), and it should be appreciated that at least one of the base 230 and the link 220 may be formed with a screw hole (not shown) positioned corresponding to the second coupling hole of the base bracket 250 and to which the screw (not shown) is coupled.

The terminal assembly 240 comprises a connecting terminal 241 to which the first cable 203 for transmitting the external signal is connectable, and a terminal supporter 243 supporting the connecting terminal 241 and rotatably coupled to at least one of the link 220 and the monitor hinge 211. In the second embodiment, the terminal assembly 240 is rotatably coupled to the monitor hinge shaft 215 of the monitor hinge 211, but it should be appreciated that the terminal assembly 240 may be accommodated in the terminal assembly housing 228 of the link 220 and rotatably coupled to the pair of first portions 220a of the link 220. That is, the terminal assembly 240 is rotatably coupled not to the monitor hinge shaft 215 but to the pair of first portions 220a. Further, according to an aspect of the invention, the terminal assembly 240 is rotatably coupled to the second end of the monitor hinge shaft 215, but may be rotatably coupled to a terminal hinge projection (not shown) separately protruding from the second end of the monitor hinge shaft 215 toward the terminal assembly 240.

The connecting terminal 241 is detachably connectable with the first cable 203 to receive the external signal such as a video signal, an audio signal, power, etc. The connecting terminal 241 may be detachably connected with a cable connector 205 provided in an end of the first cable 203, and is provided to be connected with a plurality of cable connectors 205.

The terminal supporter 243 supports the connecting terminal 241 and is formed with a shaft accommodating part 246 to be rotatably coupled to the monitor hinge shaft 215, being accommodated in the terminal assembly housing 228. That is, the terminal supporter 243 is coupled to the connecting terminal 241 by a screw or the like to support the connecting terminal 241, and accommodates a second cable 245 inwardly connected to the connecting terminal 241. Thus, the terminal supporter 243 is rotatable about a rotating axis of the monitor hinge shaft 215.

The shaft accommodating parts 246 are formed on opposite sides of the terminal supporter 243 to accommodate the pair of the monitor hinge shafts 215, respectively. Further, the monitor hinge shaft 215 is formed with a second cable through hole 217 through which the second cable 245 connected to the connecting terminal 241 inside the terminal supporter 243 is passed.

The second cable through hole 217 is formed on the center of the monitor hinge shaft 215 and allows the second cable 245 to connect the connecting terminal 241 with the monitor body 210 via the link 220.

With this configuration, the monitor 210 according to the second embodiment of the present invention is operated as follows.

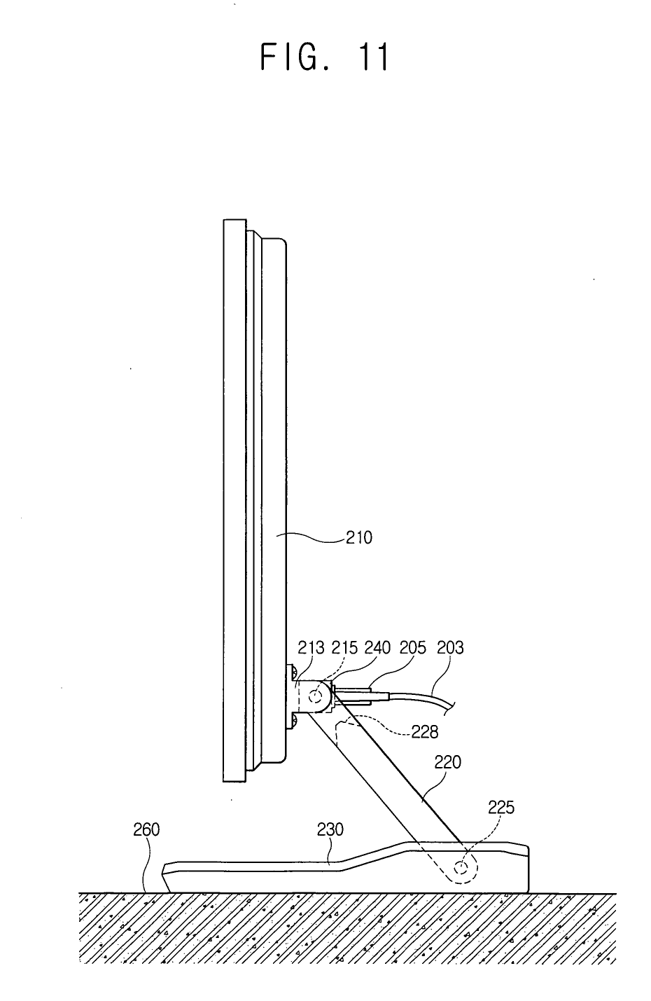

As shown in FIGS. 8 and 11, in a case of seating the monitor 201 on the horizontal surface 260, the terminal assembly 240 is rotated about the monitor hinge shaft 215 to orient the connecting terminal 241 backward, that is, away from the monitor body 210. Then, the cable connector 205 provided at the end of the first cable 203 is connected to the connecting terminal 241. The terminal assembly 240 is rotatable through an angle of at least 180 degrees.

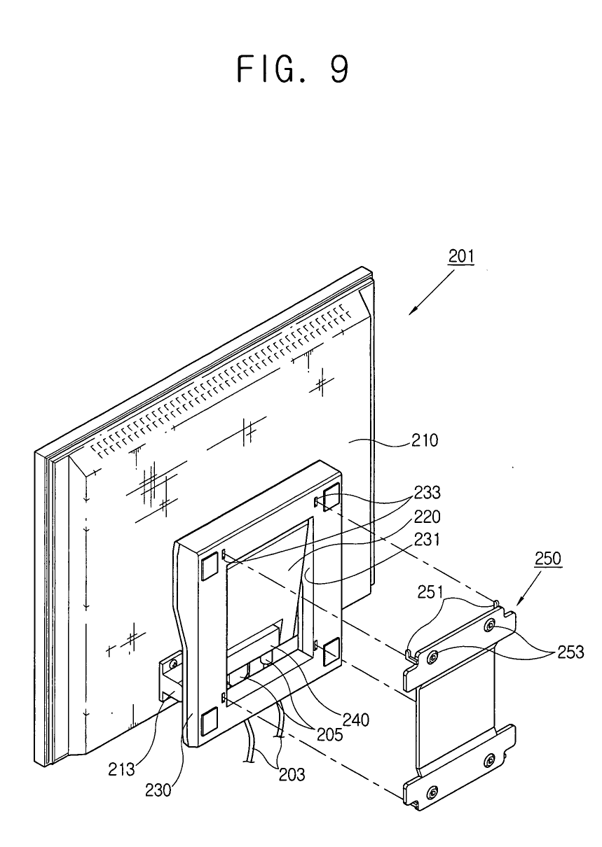

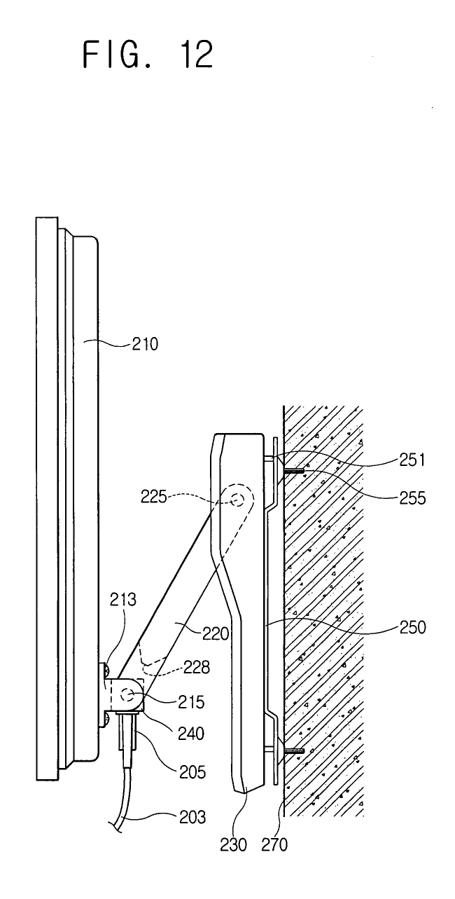

As shown in FIGS. 9 and 12, in a case of mounting the monitor 201 on the inclined surface 270, the base bracket 250 is mounted to the inclined surface 270, and the projection holders 233 of the base 230 are coupled to the projections 251 of the base bracket 250. The terminal assembly 40 is rotated about the monitor hinge shaft 215 to orient the connecting terminal 241 downward. The cable connector 205 provided in the end of the first cable 203 is connected to the connecting terminal 241 oriented downward, thereby preventing the first cable 203 from being upwardly exposed from the monitor body 210 even if the monitor 210 is tilted.

Thus, in the monitor 1 or 201 according to the embodiments of present invention, when the base is mounted to the inclined wall, the cable is not only conveniently connected because the terminal assembly connected to the cable is rotatably coupled to the monitor hinge or the link, but is also beautifully connected because the cable is prevented from being upwardly exposed from the monitor body.

As described above, the present invention provides a monitor in which a cable for transmitting an external signal is conveniently and beautifully connected.

Although a few embodiments of the present invention have been shown and described, it will be appreciated by those skilled in the art that changes may be made in these embodiments without departing from the principles and spirit of the invention, the scope of which is defined in the appended claims and their equivalents.

1. A monitor comprising:
a monitor body to display an image;
a base supporting the monitor body;
a link provided between the monitor body and the base and allowing the monitor body to be rotatable with respect to the base; and
a terminal assembly comprising:
a connecting terminal to which a cable for transmitting an external signal is connectable, and
a terminal supporter supporting the connecting terminal and rotatably coupled to the base.

2. The monitor according to claim 1, further comprising:
a base hinge provided between the link and the base and rotatably coupling the link with the base; and
a monitor hinge provided between the link and the monitor and rotatably coupling the link with the monitor.

3. The monitor according to claim 2, wherein the base is formed with a link housing to accommodate the link.

4. The monitor according to claim 3, wherein the terminal assembly is placed in a front of the link housing of the base.

5. The monitor according to claim 4, wherein the base is formed with a cable housing to accommodate at least a part of the cable.

6. The monitor according to claim 1, further comprising a base bracket adapted to couple the base and an inclined surface so that the base is mountable to the inclined surface.

7. The monitor according to claim 1, further comprising a terminal hinge provided between the terminal assembly and the base, and supporting the terminal assembly to be rotatable to allow the connecting terminal to be oriented frontward or backward with respect to the base.

8. The monitor according to claim 7, wherein the terminal hinge comprises:
a terminal hinge shaft provided in one of the terminal supporter and the base and disposed on an axis parallel with a rotating axis of the monitor body, and
a terminal hinge shaft accommodating part provided in the other one of the terminal supporter and the base and rotatably accommodating the terminal hinge shaft.

9. The monitor according to claim 8, wherein the terminal hinge shaft is formed with a cable through hole through which another cable connected to the connecting terminal inside the terminal supporter is passed.

10. A monitor comprising:
a monitor body to display an image;
a base supporting the monitor body;
a link provided between the monitor body and the base;
a monitor hinge provided between the link and the monitor body and rotatably coupling the link with the monitor body; and
a terminal assembly comprising:
a connecting terminal to which a cable for transmitting an external signal is connectable, and
a terminal supporter supporting the connecting terminal and rotatably coupled to one of the link and the monitor hinge.

11. The monitor according to claim 10, wherein the monitor hinge comprises:
a monitor supporter coupled to the monitor body, and
a monitor hinge shaft coupled between the monitor supporter and the link and allowing the monitor supporter to be rotatable with respect to the link.

12. The monitor according to claim 11, wherein a terminal assembly housing is formed in an end portion of the link coupled to the monitor hinge shaft, to accommodate the terminal assembly.

13. The monitor according to claim 12, wherein the terminal assembly is coupled to the monitor hinge shaft and is rotatable about a rotating axis of the monitor hinge shaft.

14. The monitor according to claim 13, wherein the monitor hinge shaft is formed with a cable through hole through which a second cable connected to the connecting terminal is passed.

15. The monitor according to claim 10, further comprising a base hinge provided between the link and the base and rotatably coupling the link with the base.

16. The monitor according to claim 10, further comprising a base bracket adapted to the base and an inclined surface so that the base is mountable to the inclined surface.

17. A monitor comprising:
a base having a mounting surface;
a monitor body having a front side to display an image and a backside;
a link having a first end and a second end;
a first hinge which rotationally couples the base and the first end of the link;
a second hinge which rotationally couples the second end of the link and the backside of the monitor body; and
a connection terminal operatively connected with the monitor body via a first cable, and adapted to receive a second cable to provide an operating signal for the monitor body, the connection terminal rotatably disposed for orientation at various angles relative to the mounting surface of the base,

18. The monitor according to claim 17, wherein the base comprises an opening for accommodating the link and the connection terminal is rotatably disposed in the opening at a position which permits the link to be rotated into the opening.

19. The monitor according to claim 18, wherein the connection terminal is rotatable relative to the mounting surface of the base through an angle of at least 180 degrees.

20. The monitor according to claim 17, wherein the connection terminal is rotatably disposed parallel to an axis of rotation of the second hinge.

21. The monitor according to claim 20, wherein the connection terminal is rotatable relative to the mounting surface of the base through an angle of at least 180 degrees.

22. The monitor according to claim 17, wherein:
the monitor further comprises a mounting plate having a plurality of projections transverse to a mounting surface of the plate; and
the mounting surface of the base further comprises a plurality of openings adapted to engage the plurality of projections to support the base on an inclined surface.

23. The monitor according to claim 17, wherein an axis of rotation of the connection terminal is parallel to an axis of rotation of the first hinge.

24. The monitor according to claim 20, wherein the first cable is positioned along the axis of rotation of the second hinge.
